(19) United States
(12) Patent Application Publication
(10) Pub. No.: US 2005/0271830 A1
(43) Pub. Date: Dec. 8, 2005

(54) Chemical vapor deposition method

(76) Inventors: Yun-Soo Park, Osan-si (KR); Jong-Kook Kim, Osan-si (KR); Myoung-Hun Jung, Suwon-si (KR); Young-Su Cho, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/143,579

(22) Filed: Jun. 3, 2005

(30) Foreign Application Priority Data
Jun. 4, 2004 (KR) 2004-40830

(51) Int. Cl. C23C 16/00

(52) U.S. Cl. 427/569; 427/248.1

(57) ABSTRACT

A chemical vapor deposition method forms a dielectric layer on a wafer with a plasma reaction generated by applying radio frequency power to electrodes positioned at upper and lower portions of a chamber. The method includes the steps of placing the wafer into the chamber, forming a first dielectric layer on the wafer with the plasma reaction by supplying first and second reactive gases in the chamber, and forming a second dielectric layer which has a density higher than that of the first dielectric layer on the first dielectric layer by stopping the supply of the second reactive gas while the plasma reaction is maintained, and by using the first reactive gas continuously supplied into the chamber and the residual second reactive gas left in the chamber.

### BACKGROUND OF THE INVENTION

1. Technical Field

The present invention generally relates to a method of manufacturing a semiconductor device. More particularly, the present invention relates to a chemical vapor deposition method using a plasma enhanced chemical vapor deposition apparatus to manufacture a semiconductor device.

A claim of priority is made to Korean Patent Application No. 2004-40830, filed Jun. 4, 2004, the disclosure of which is hereby incorporated in its entirety.

2. Discussion of Related Art

Generally, a semiconductor device is manufactured by such processes as deposition, photo lithography, etching, and diffusion. These processes are selectively repeated several times to manufacture the semiconductor device. In particular, the deposition process is an essential process in the manufacturing of the semiconductor device. The deposition process is a process which deposits a layer on a substrate. Exemplary deposition processes include a sol-gel process, a sputtering process, an electroplating process, an evaporation process, a chemical vapor deposition process, a molecule beam epitaxy process, and an atomic layer deposition process.

The chemical vapor deposition process is generally used because of its excellent uniform deposition characteristics. Exemplary chemical vapor deposition processes include a Low Pressure Chemical Vapor Deposition (LPCVD) process, an Atmospheric Pressure Chemical Vapor Deposition (APCVD) process, a Low Temperature Chemical Vapor Deposition (LTCVD) process, and a Plasma Enhanced Chemical Vapor Deposition (PECVD) process.

Conventionally, the PECVD process is performed by introducing semiconductor substrates into a process chamber of a chemical vapor deposition apparatus, and then performing the PECVD process to deposit layers on the semiconductor substrates. However recently, as semiconductor devices become highly integrated and the size of substrates become larger, only a single semiconductor substrate can fit into a process chamber. After the PECVD process with respect to one semiconductor substrate is completed, cleaning and purging processes are performed to remove residual gases and reactive products in the process chamber.

U.S. Pat. No. 5,573,981, for example, discloses such a conventional chemical vapor deposition method.

Hereinafter, a conventional chemical vapor deposition apparatus and a chemical vapor deposition method using the apparatus will be explained with reference to the attached drawings.

FIG. 1 is a cross-sectional view of a conventional chemical vapor deposition apparatus, and FIG. 2 is a flow chart to explain the conventional chemical vapor deposition method.

As shown in FIG. 1, the conventional chemical vapor deposition apparatus comprises a process chamber (not shown), a single-pole electrostatic chuck 9, which vertically fixes a wafer 3 by means of a wafer support 1. An inner electrode 2, which is insulated from wafer support 1 is located in electrostatic chuck 9, and is employed to generate a plasma reaction. A heater 4, which heats wafer 3 to a predetermined temperature is installed in a lower portion of electrostatic chuck 9. A conversion switch 5, when turn on generates an AC power from grounded DC power sources 6a and 6b. The AC power passes through a filter 8 and supplies power to inner electrode 2. Although not shown, the chemical vapor deposition apparatus further comprises a reactive gas supplying part and a purge gas supplying part that supply a reactive gas P and a purge gas in a direction perpendicular to the top surface of the wafer in the process chamber, and a pump which discharges the reactive gas P and the purge gas from the process chamber to regulate the pressure.

Inner electrode 2 excites reactive gases such as silane gas (SiH₄) and nitrous oxide gas (N₂O) to create a plasma reaction, and a layer of silicon dioxide is deposited on wafer 3. Therefore, since the conventional chemical vapor deposition apparatus generates plasma reaction with a single electrode, it is refer to as an Electron Cyclotron Resonance-Chemical Vapor Deposition (ECR-CVD) apparatus.

Electrostatic chuck 9 vertically positions wafer 3. Reactive gases P supplied through the reactive gas supplying part flow into the process chamber towards wafer 3 under pressure. A silicon oxide film is formed on wafer 3 by a chemical reaction of the reactive gas ions generated by the plasma reaction. Since micro particles, which are relatively heavy polymers, are generated by a chemical reaction between excessive reactive gas ions, the micro particles drop to the bottom of the process chamber. However, the micro particles, which are charged, are attracted to the electrostatic force of electrostatic chuck 9, and may settle on wafer 3.

The chemical vapor deposition method using the conventional chemical vapor deposition apparatus is as follows.

Referring to FIGS. 1 and 2, a wafer 3 is inserted into a process chamber. Wafer 3 is fixed to an electrostatic chuck 9, and then the process chamber is pressurized to a predetermined pressure. (S10)

Next, reactive gases such as silane gas (SiO₄) and nitric acid gas (N₂O) are supplied to the process chamber. Then, high radio frequency power is applied to an inner electrode 2, a plasma reaction is induced, and then a silicon oxide film is formed on wafer 3. (S20)

Next, after the formation of the silicon oxide film, the supply of the silane and the nitrous oxide gases are shut off, and then the gases are discharged from the process chamber. (S30) Afterwards, the interior of the process chamber is purged. At this time, the pressure in the interior of the process chamber is reduced to a lower pressure than when reactive gases P were being supplied. As reactive gases P are purged from the process chamber, plasma reaction is reduced or ceases. At the end of this process, micro particles formed by the reactive gases P may remain in the inner surface of the process chamber.

After the silane gas and the nitrous oxide gas are discharged, then nitrous oxide gas alone is selectively supplied into the process chamber. (S40)

Finally, a plasma reaction is generated in the process chamber with nitrous oxide gas to reduce the radius of micro particles to about 0.3 μm. (S50)

When the deposition of the silicon oxide film is completed, the process is repeated.

As described above, the conventional chemical vapor deposition method has the following problems.

First, after the silicon oxide film is formed by the silane gas and the nitrous oxide gas, the reactive gases induce micro particles by a chemical reaction in the process of discharging and purging the reactive gases. The micro particles may adhere to the wafer and thus product characteristics deteriorate, which lowers the manufacturing production yield.

Second, after the silicon oxide film is formed, the plasma reaction is stopped in the process of discharging and purging the reactive gases in the process chamber, and although the plasma reaction is started again, the micro particles generated during the stopped period can form on the wafer, which lowers the manufacturing product yield.

Therefore, it would be desirable to provide an improved method which maximizes the product yield rate by preventing micro particles from forming on semiconductor wafers during a manufacturing process.

### SUMMARY OF THE INVENTION

In one aspect of the present invention provides a chemical vapor deposition method by placing a wafer into a process chamber, supplying a first and second reactive gases into the process chamber, supplying radio frequency power to an electrode disposed in the process chamber to create a plasma reaction with the reactive gases to deposit a first dielectric film on the wafer, and shutting off the supply of the second reactive gas while continuing to supply the first reactive gas to the process chamber, wherein residual gas reacts with the first reactive gas to deposit a second dielectric film on the first dielectric film.

Another aspect of the present invention provides a chemical vapor deposition method by placing a wafer into a process chamber, supplying nitrous oxide gas and silane gas and into the process chamber, supplying radio frequency power to an electrode disposed in the process chamber to create a plasma reaction with the nitrous oxide gas and the silane gas to deposit a first dielectric film on the wafer, and shutting off the supply of the silane gas while continuing to supply the nitrous oxide gas to the process chamber, wherein residual silane gas reacts with the nitrous oxide gas to deposit a second dielectric film on the first dielectric film, where the second dielectric film has a greater density than the first dielectric film.

And another aspect of the present invention provides a chemical vapor deposition method by placing a wafer into a process chamber, supplying first, second, and third reactive gases, and a purging gas into the process chamber, supplying radio frequency power to an electrode disposed in the process chamber to create a plasma reaction with the first, second, and third reactive gases to deposit a first dielectric film on the wafer, and shutting off the supply of the second and third reactive gases while continuing to supply the first reactive gas to the process chamber, wherein residual gases react with the first reactive gas to deposit a second dielectric film on the first dielectric film.

### BRIEF DESCRIPTION OF THE DRAWINGS

The above and other aspects of the present invention will become more apparent by the detailed description of the preferred embodiments thereof with reference to the attached drawings in which:

FIG. 1 is a cross-sectional view schematically illustrating a conventional chemical vapor deposition apparatus;

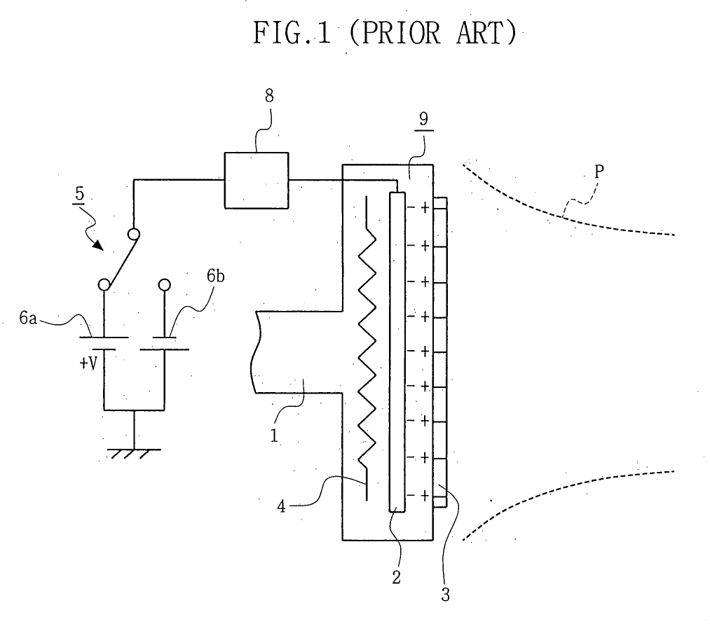

FIG. 2 is a flow chart to schematically explain a conventional chemical vapor deposition method;

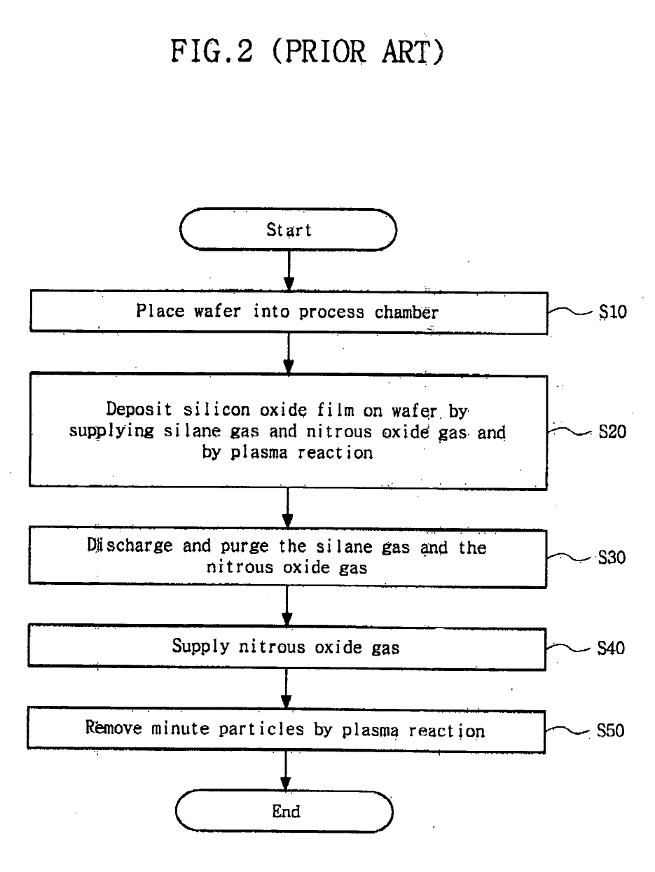

FIG. 3 is a cross-sectional view schematically illustrating an embodiment of a chemical vapor deposition apparatus according to the present invention;

FIG. 4 is a flow chart to schematically explain a chemical vapor deposition method according to an embodiment of the present invention;

FIG. 5 a graph representing the number of micro particles generated over a period of time when a second oxide film is formed by the chemical vapor deposition method according to an embodiment of the present invention; and

FIG. 6 is a flow chart to schematically explain a chemical vapor deposition method according to another embodiment of the present invention.

### DETAILED DESCRIPTION OF THE INVENTION

The present invention will now be described with reference to the accompanying drawings, in which preferred embodiments of the present invention are shown. However, the present invention should not be construed as limited to the embodiments set forth herein. Rather, these embodiments are provided as to illustrate the invention. Like numbers refer to like elements.

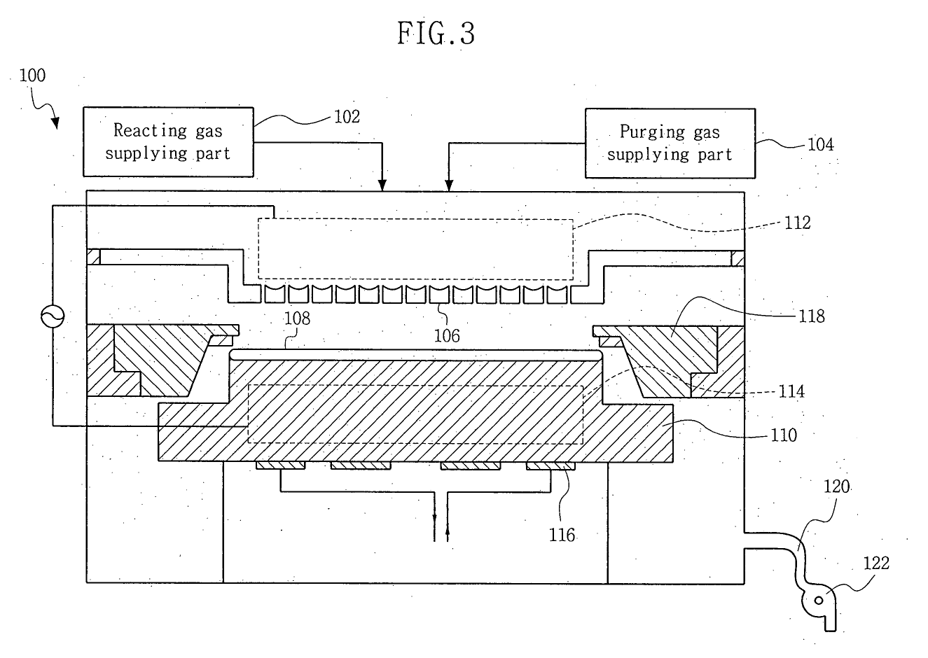

FIG. 3 is a cross-sectional view to schematically illustrate an embodiment of a chemical vapor deposition apparatus according to the present invention.

As shown in FIG. 3, the chemical vapor deposition apparatus comprises a process chamber 100 which provides a process area isolated from the exterior environment; a reactive gas supplying part 102, which supplies reactive gases into process chamber 100; a purging gas supplying part 104; a shower head 106, which uniformly sprays the reactive gases supplied through reactive gas supplying part 102; a susceptor 110 disposed opposite shower head 106 to support a wafer 108; upper and lower electrodes 112 and 114 disposed at an upper portion of shower head 106 and a lower portion of susceptor 110, respectively, to generate a plasma reaction; a heater block 116 to heat wafer 108 during the plasma reaction; an edge ring 118, which protects an edge of wafer 108 from the plasma reaction generated by high radio frequency power supplied to upper and lower electrodes 112 and 114 powered by an outside AC source; and, a pump 122, which discharges reactive gases and purging gas through a vacuum discharging pipe 120, and to maintain vacuum within the interior of process chamber 100. Although not shown, a matching device to match impedance of high radio frequency power applied to upper and lower electrodes 112 and 114 is provided.

Since the plasma reaction is generated at a temperature of about 390° C., wafer 108 is heated by heater block 116 to improve the uniformity of the dielectric layer, e.g., silicon oxide film or silicon nitrogen oxide film.

The reactive gases supplied through shower head 106 form a dielectric layer on wafer 108 through a plasma reaction, and the non-reacted reactive gases are discharged by pump 122 through vacuum discharging pipe 120.

High radio frequency power supplied to upper and lower electrodes 112 and 114 is preferably supplied by an AC voltage, which turns the reactive gases into a plasma state, and generates a plasma reaction on wafer 108. Micro particles, which are generated during the plasma reaction or when the reaction is stopped, are discharged through vacuum discharging pipe 120 along with the flow of the reactive gas. That is, since susceptor 110 only supports the weight of wafer 108, and does not hold wafer 108 by an electrostatic force, the micro particles are discharged through vacuum discharging pipe 120 by pump 122.

A plasma chemical vapor deposition method will now be described.

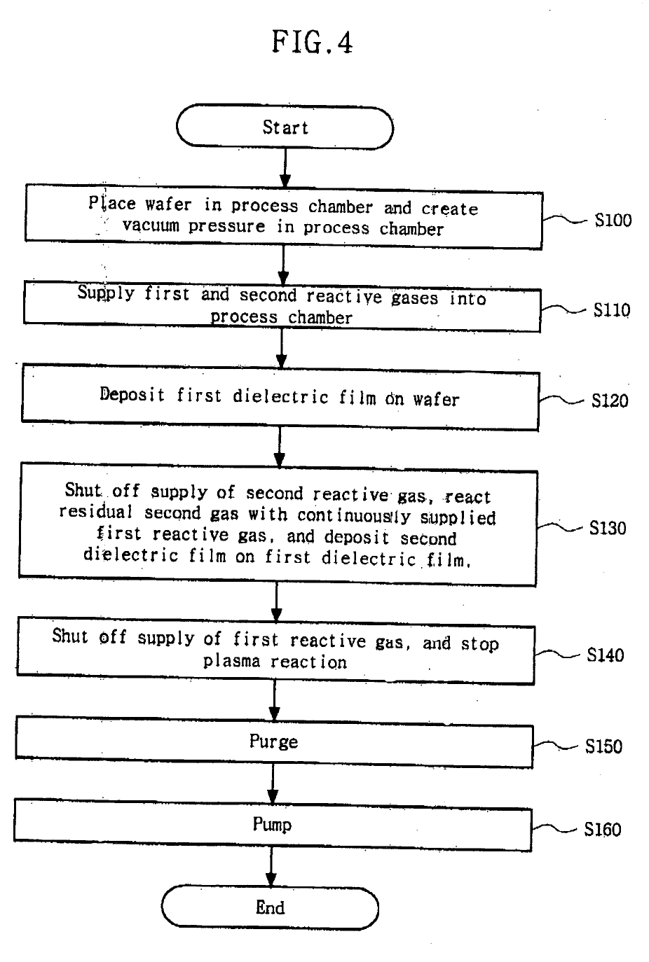

As shown in FIG. 4, a wafer 108 is inserted into a process chamber 100 and placed on a susceptor 110. A pump 122 removes air within process chamber 100, and creates a vacuum pressure between about 100 mmTorr though 10000 mmTorr within process chamber 100. (S100) A first reactive gas, preferably nitrous oxide gas, and a purging gas, preferably nitrogen gas, are supplied through a reactive gas supplying part 102 and a purging gas supplying part 104, respectively. Although the vacuum pressure in process chamber 100 may vary depending on the type of process, pump 122 continues to pump and maintain vacuum pressure in process chamber 100.

Plasma reaction is generated by supplying the first reactive gas with a second reactive gas, preferably silane gas, to process chamber 100, and then a high radio frequency (RF) field is applied to upper and lower electrodes 112 and 114. The RF field energizes the reactive gases to from a plasma state. (S110, S120)

A first dielectric layer, preferably a first silicon oxide film, is deposited on wafer 108 by the plasma reaction. Also wafer 108 is heated by a heater block 116 to a temperature of about 390° C.

The plasma reaction equation for silane gas and nitrous oxide gas is as follows.
SiH₄+2N₂O+Electric Energy→SiO₂+2N₂↑+2H₂ ↑+Heat Energy (Reaction Equation)

For example, silane gas is supplied into process chamber 100 at a flow rate of about 90 sccm and nitrous oxide is supplied at a flow rate of about 1800 sccm. A high radio frequency power of about 190 W is applied to upper and lower electrodes 112 and 114 to generate the plasma reaction, and then the first dielectric film is formed on wafer 108 at a deposition rate of about 180 Å per second.

Although nitrogen and hydrogen gases are discharged by pump 122, and since silane gas and nitrous oxide gas quickly react by the plasma reaction to rapidly deposit the first dielectric layer, significant amounts of hydrogen gas reside in the first silicon oxide film. Therefore, the dielectric film has a thin structure, and the density of the first dielectric film, for example silicon oxide film, is much smaller than that of a crystalline silicon oxide film.

For example, when deionized water which is used in a subsequent photo lithography process and a cleaning process comes in contact with the first dielectric film, the hydrophilic first dielectric film will absorb the deionized water.

After a predetermined time, e.g., about 5 to 30 seconds, and after the deposition of the first dielectric film, the supply of the silane gas into process chamber 100 is shut off. Residual silane gas in process chamber 100, and continuously supplied nitrous oxide gas, react to deposit a second dielectric layer, e.g, a second silicon oxide film, on wafer 108. (S130) The second dielectric film is formed at a vacuum pressure between about several mmTorr to tens of Torr.

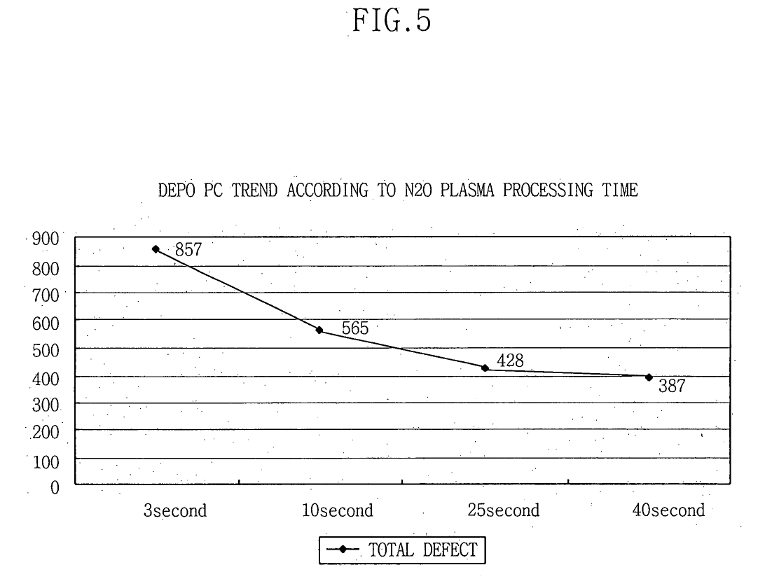

FIG. 5 is a graph illustrating the number of micro particles generated over time when the second dielectric film is deposited. In FIG. 5, as residual silane gas in process chamber 100 and nitrous oxide gas react, the number of micro particles generated by the plasma reaction decreases over time.

In the graph of FIG. 5, the horizontal axis represents the time after the supply of silane gas supplied into process chamber 100 is shut off and only nitrous oxide gas is supplied. The vertical axis represents the number of micro particles which have a diameter of about 0.1 μm. The number of micro particles formed on the second silicon oxide film is decreases over time due to reduced amounts of silane gas.

For example, when the plasma reaction is continuously generated by supplying the high radio frequency power of 190 W and the nitrous oxide gas is supplied at a flow rate of about 1800 sccm, the second silicon oxide film is deposited on the first silicon oxide film at a rate of about 3 Å per second. The second silicon oxide film is deposited for a predetermined time, for example, 20 seconds, and can be further deposited even after the 20 seconds. In the first preferred embodiment, by supplying the nitrous oxide gas into process chamber 100 for about 20 seconds, the second silicon oxide film is deposited to about 50 Å to 60 Å.

Since the second dielectric film has a relatively high density compared with the first dielectric film, deionized water is not absorbed by the second dielectric, and therefore, no water marks are generated.

Then in step 140, the supply of nitrous oxide gas into process chamber 100 is shut off, and the plasma reaction is stopped. Nitrogen gas is again introduced to purge process chamber 100. (S150). The purging nitrogen gas and any remaining reactive gases are discharged from process chamber 100 through a discharging pipe 120. (S160)

Wafer 108 is then transferred to load lock chamber (not shown), thus completing the chemical vapor deposition process.

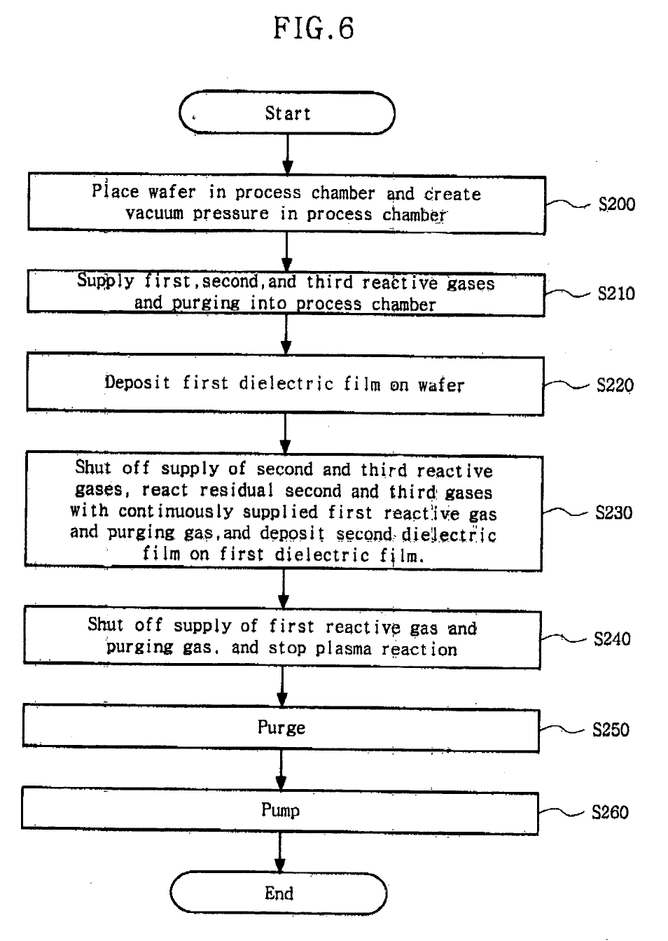

FIG. 6 is a flow chart to schematically explain a chemical vapor deposition method according to another embodiment of the present Invention.

As shown in FIG. 6, a wafer 108 is inserted into a process chamber 100. Wafer 108 is fixed by a susceptor 110. (S200) A vacuum pressure is created in process chamber 100 of between about 100 mmTorr to about 10000 mmTorr, by pumping air out of process chamber 100 by a pump 122.

Then, a first reactive gas, preferably nitrous oxide gas, a second reactive gas, preferably silane gas, a third reactive gas, preferably ammonia gas, and a purging gas, preferably nitrogen gas are supplied to process chamber 100. High radio frequency power is applied to upper and lower electrodes 112 and 114 to create a plasma reaction. (S210, S220) The plasma reaction causes a first dielectric layer, e.g., silicon nitrogen oxide film (SiON), to deposit on wafer 108.

The plasma reaction equation for the first, second, third reactive gases and the purging gas is as follows.
2SiH₄+2N₂O+2NH₃+N₂+Electric Energy→2SiON+3N₂₁↑+7H₂↑+Heat Energy (Reaction Equation)

For example, the purging gas is supplied at a flow rate of about 3500 sccm; the second reactive gas is supplied at a flow rate of about 130 sccm; the first reactive gas is supplied at a flow rate of about 120 sccm; the third reactive gas supplied at a flow rate of about 100 sccm; and the high radio frequency power is about 100 W. A first dielectric film is formed at a deposition rate of 180 Å per second on wafer 108.

Then, nitrogen gas and hydrogen gas are discharged out of process chamber 100 through discharging pipe 120 by pump 122, but because the reactive gases are rapidly reacting by the plasma reaction and the first dielectric film is rapidly formed, a substantial amount of hydrogen gas resides in the first silicon nitrogen oxide film.

Therefore, the first dielectric film, for example silicon nitrogen oxide film, has a thin structure, and its density is much lower than that of a crystalline silicon nitrogen oxide film.

After a predetermined time has passed, e.g., about 5 to 30 seconds, and after the first dielectric has been deposited on wafer 108, the supply of the second reactive gas and the third reactive gas into process chamber 100 are shut off, but the purging gas and first reactive gas are continuously supplied into process chamber 100. Then, a second dielectric film, for example silicon nitrogen oxide film, is formed on wafer 108 by maintaining the plasma reaction and reacting nitrogen gas and the first reactive gas with the residual second and third reactive gases remaining within process chamber 100.

The second dielectric film is deposited on the first dielectric film at a deposition rate of about 1 Å to 2 Å per second.

Therefore, according to the second embodiment of the present invention, shutting off supply of one or more of the reactive gas does not stop the plasma reaction. And, a second dielectric film of a different density than the first dielectric film is deposited.

After the second dielectric film is formed, the supply of the first reactive gas and the purging gas are shut off and the plasma reaction is stopped. (S240) Process chamber 100 is purged with the purging gas. (S250) Then, the purging gas and any remaining residual gases are discharged out of the process chamber 100 through discharging pipe 120. (S260)

Wafer 108 is transferred to a load lock chamber (not shown), thus completing the chemical vapor deposition process.

The present invention has been described using preferred exemplary embodiments. However, it is to be understood that the scope of the present invention is not limited to the disclosed embodiments. On the contrary, the scope of the present invention is intended to include various modifications and alternative arrangements within the capabilities of persons skilled in the art using presently known or future technologies and equivalents.

1. A chemical vapor deposition method, comprising:
placing a wafer into a process chamber;
supplying a first and second reactive gases into the process chamber;
supplying radio frequency power to an electrode disposed in the process chamber to create a plasma reaction with the reactive gases to deposit a first dielectric film on the wafer; and
shutting off the supply of the second reactive gas while continuing to supply the first reactive gas to the process chamber, wherein residual gas reacts with the first reactive gas to deposit a second dielectric film on the first dielectric film.

2. The method of claim 1, wherein the first and second reactive gases comprises silane gas and nitrous oxide gas.

3. The method of claim 2, wherein the second reactive gas is the silane gas.

4. The method of claim 2, wherein the silane gas is supplied at a flow rate of about 190 sccm, and the nitrous oxide gas is supplied at a flow rate of about 1800 sccm.

5. The method of claim 1, wherein the high radio frequency power is 190 W.

6. The method of claim 1, wherein the wafer is heated to about 390° C. during the plasma reaction.

7. The method of claim 1, further comprising:
purging the process chamber with a purging gas; and
discharging the purging gas and any residual reactive gases in the process chamber.

8. A chemical vapor deposition method, comprising:
placing a wafer into a process chamber;
supplying nitrous oxide gas and silane gas and into the process chamber;
supplying radio frequency power to an electrode disposed in the process chamber to create a plasma reaction with the nitrous oxide gas and the silane gas to deposit a first dielectric film on the wafer; and
shutting off the supply of the silane gas while continuing to supply the nitrous oxide gas to the process chamber, wherein residual silane gas reacts with the nitrous oxide gas to deposit a second dielectric film on the first dielectric film, where the second dielectric film has a greater density than the first dielectric film.

9. The method of claim 8, wherein the first dielectric film is formed by supplying the nitrous oxide gas and the silane gas for 5 to 30 seconds.

10. The method of claim 8, wherein the second dielectric film is formed by supplying only the nitrous oxide gas for 20 seconds.

11. The method of claim 8, wherein the silane gas is supplied at a flow rate of about 190 sccm, and the nitrous oxide gas is supplied at a flow rate of about 1800 sccm.

12. The method of claim 8, wherein the radio frequency power is 190 W.

13. The method of claim 8, wherein the wafer is heated to about 390° C. during the plasma reaction.

14. The method of claim 8, further comprising:
purging the process chamber with a purging gas; and
discharging the purging gas and any residual reactive gases in the process chamber.

15. A chemical vapor deposition method, comprising:
placing a wafer into a process chamber;
supplying first, second, and third reactive gases, and a purging gas into the process chamber;
supplying radio frequency power to an electrode disposed in the process chamber to create a plasma reaction with the first, second, and third reactive gases to deposit a first dielectric film on the wafer; and
shutting off the supply of the second and third reactive gases while continuing to supply the first reactive gas to the process chamber, wherein residual gases react with the first reactive gas to deposit a second dielectric film on the first dielectric film.

16. The method of claim 15, wherein the first, second, and third reactive gases are nitrous oxide gas, silane gas, and ammonia gas, respectively, and the purging gas is nitrogen gas.

17. The method of claim 16, wherein the first and second gases that are shut off are the silane gas and the ammonia gas.

18. The method of claim 15, wherein, the first reactive gas is supplied at a flow rate of about 120 sccm, the second reactive gas is supplied at a flow rate of about 130 sccm, and the third reactive gas is supplied at a flow rate of about 100 sccm, and the purging gas is supplied at a flow rate of about 3500 sccm.

19. The method of claim 15, wherein the radio frequency power is 100 W.

20. The method of claim 15, further comprising:
after the second dielectric is formed, purging the process chamber with the purging gas; and
discharging the purging gas and any residual reactive gases in the process chamber.
